(19) United States
(12) Patent Application Publication
(10) Pub. No.: US 2006/0017160 A1
(43) Pub. Date: Jan. 26, 2006

(54) Structure and formation method of conductive bumps

(75) Inventor: Min-Lung Huang, Kaohsiung City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/185,831

(22) Filed: Jul. 21, 2005

(30) Foreign Application Priority Data
Jul. 23, 2004 (TW) 093122194

(51) Int. Cl. H01L 21/44; H01L 23/48; H01L 23/52

(52) U.S. Cl. 257/737; 438/613; 438/614; 257/750

(57) ABSTRACT

A method and structure for a conductive bump are provided herein. A conductive surface is provided on a wafer. A conductive barrier layer and a conductive wetting layer on a part of the conductive surface have a bottom and a side wall and further reach up a top surface. The conductive wetting and barrier layers constitute inside and outside side walls, respectively. A conductive seed layer covers the conductive wetting layer and the top surface. Another conductive barrier and conductive bump are subsequently formed on the conductive seed layer.

### BACKGROUND OF THE INVENTION

1. Field of the Invention

The present invention generally relates to a structure and a formation method of conductive bumps and, more particularly to conductive bumps each having an under bump metallurgy layer with a side wall.

2. Discussion of the Related Art

With the technology of the integrated circuit in development the qualities on the package of the integrated circuit is in demand. Ball Grid Array Package (BGA) is mostly applied to high-pin chips, such as picture chips or chip sets. The substrate types of BGA include various types: Plastic BGA (PBGA), Ceramic BGA (Ceramic BGA), Flip Chip BGA (FCBGA), Tape BGA (TBGA) and Cavity Down PBGA. For example, FCBGA is to assign gold studs or solder bumps on an IC chip for connecting with a print circuit board.

For example, shown in FIG. 1 is a cross-sectional diagram illustrating a solder ball by thin film deposition in accordance with the prior art. Depicted as FIG. 1, a bond pad 12, a passivation layer 14, a conductive layer 20 and a solder ball 22 on a silicon wafer 10. The bond pad 12, such as an aluminum or copper pad, is configured for connecting with other structure or device. The passivation layer 14, configured for protecting and planarizing a semiconductor structure, exposes a surface 13 of the bond pad 12. The conductive layer 20, such as an under bump metallurgy layer (UBM layer) formed by sputtering, covers the passivation 14 layer and the surface 13 of the bond pad 12. The under bump metallurgy layer consisted of an adhesion/diffusion barrier layer 16 and a wetting layer 18 is configured for improving the connection of a solder ball 22 and the bond pad 12.

An issue on solder balls is derived from a reflow process. During reflow process, nickel elements in the solder ball 22 diffuse downward to the wetting layer 18 and react with copper in the wetting layer 18 to form an intermetallic component (IMC) of Cu₃Sn. The IMC would not prevent the nickel elements in the solder ball 22 from diffusing downward to the wetting layer 18. In such a condition, the nickel elements in the solder ball 22 are consumed heavily and the IMC of Cu₃Sn with the excess thickness is formed. Moreover, the nickel elements in the solder ball 22 also diffuse into the wetting layer 18 through the side wall of the UBM conductive layer 20, so that the IMC of Cu₃Sn is formed by reacting with the copper elements of the wetting layer 18. The IMC with the excess thickness makes the solder ball 22 easily facture in a test of heat fatigue. Furthermore, the heavy consumption of the nickel elements of the solder ball 22 makes the solder ball 22 with little area connect with a printed circuit board and further the poor connection during sequential processes. Accordingly, it is important to avoid the formation of the excess IMC for improving the connection.

### SUMMARY OF THE INVENTION

It is one of objectives of the present invention to provide a conductive bump herein for preventing nickel elements from diffusing into a wetting layer. With the addition of a conductive barrier layer between the solder ball and the wetting layer would block the diffusion of the nickel elements.

It is another one of objectives of the present invention to provide a conductive bump with a cup structure of adhesion/diffusion barrier layer to prevent the nickel elements from diffusing through the UBM layer.

It is still another one of objectives of the present invention to provide the formation method of conductive bumps. An adhesion/diffusion barrier with a side wall would prevent the nickel elements from diffusing through the side wall of the UBM for fear of the formation of the excess IMC.

Accordingly, a conductive bump structure and the formation method are provided herein. A conductive surface is provided on a wafer and a first conductive barrier layer is formed on a portion of the conductive surface. The first conductive barrier layer has a bottom and a side wall. The conductive wetting layer covers the bottom and the side wall. The conductive wetting layer and the side wall reach up a same top surface. The conductive seed layer covers the conductive wetting layer and the top surface. The second conductive barrier layer is formed on the conductive seed layer and then the conductive bump is formed on the second conductive barrier layer.

### BRIEF DESCRIPTION OF THE DRAWINGS

FIG. 1 is a cross-sectional diagram illustrating a solder ball by thin film deposition in accordance with the prior art.

FIG. 2A to FIG. 2F are cross-sectional diagrams illustrating the formation of conductive bumps in accordance with one embodiment of the present invention.

FIG. 3 is a cross-sectional diagram illustrating a conductive bump in accordance with another one embodiment of the present.

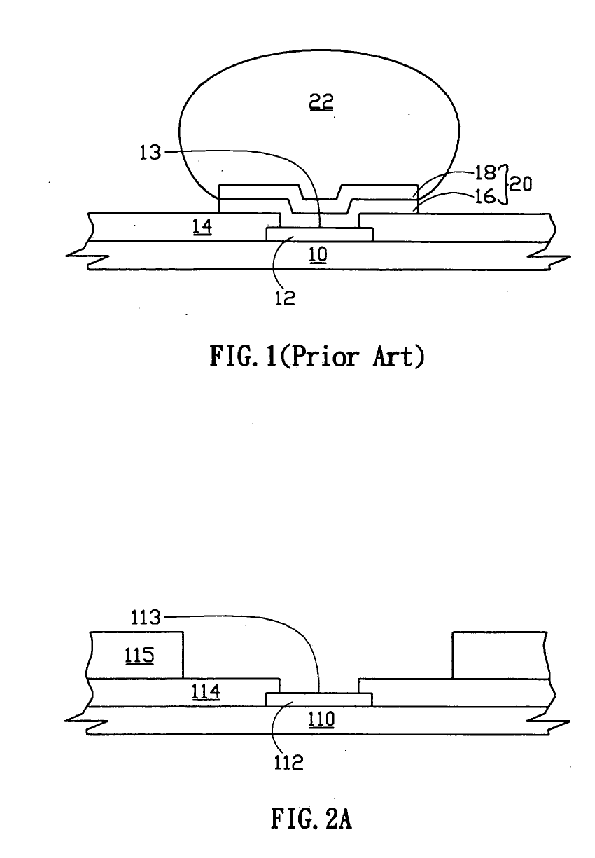

### DETAILED DESCRIPTION OF THE INVENTION

The following description is of the best presently contemplated mode of carrying out the present invention. This description is not to be taken in a limiting sense but is made merely for the purpose of describing the general principles of the invention. The scope of the invention should be determined by referencing the appended claims.

A conductive bump structure and the formation are provided herein. A conductive surface is provided on a wafer. The under bump metallurgy layer is formed on the conductive surface. The under bump metallurgy layer has a first conductive barrier layer, a conductive wetting layer, a conductive seed layer and a second conductive barrier layer. The first conductive barrier layer is in a cup shape and with a bottom attaching the conductive surface and a peripheral flange. The conductive wetting layer covers the bottom and an inside side wall of the peripheral flange. The conductive wetting layer and the peripheral flange reach up a same top surface. The conductive seed layer covers the conductive wetting layer and the top surface. The second conductive barrier layer is formed on the conductive seed layer. The conductive bump is formed on the under bump metallurgy layer.

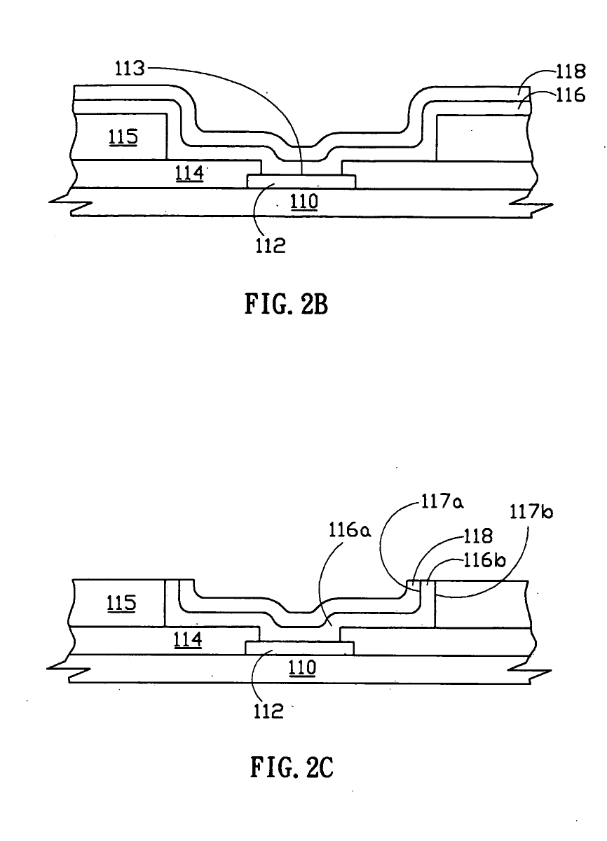

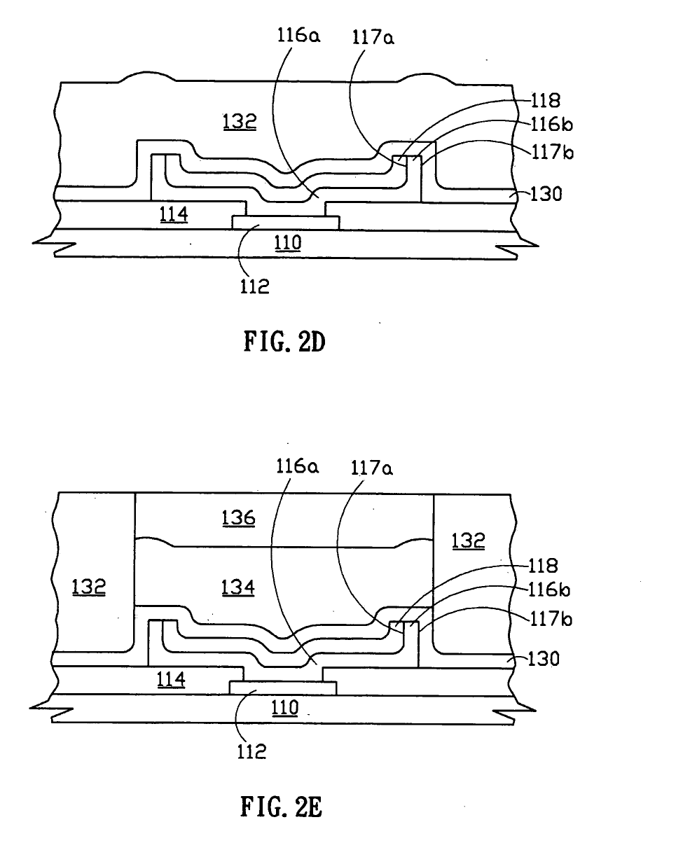

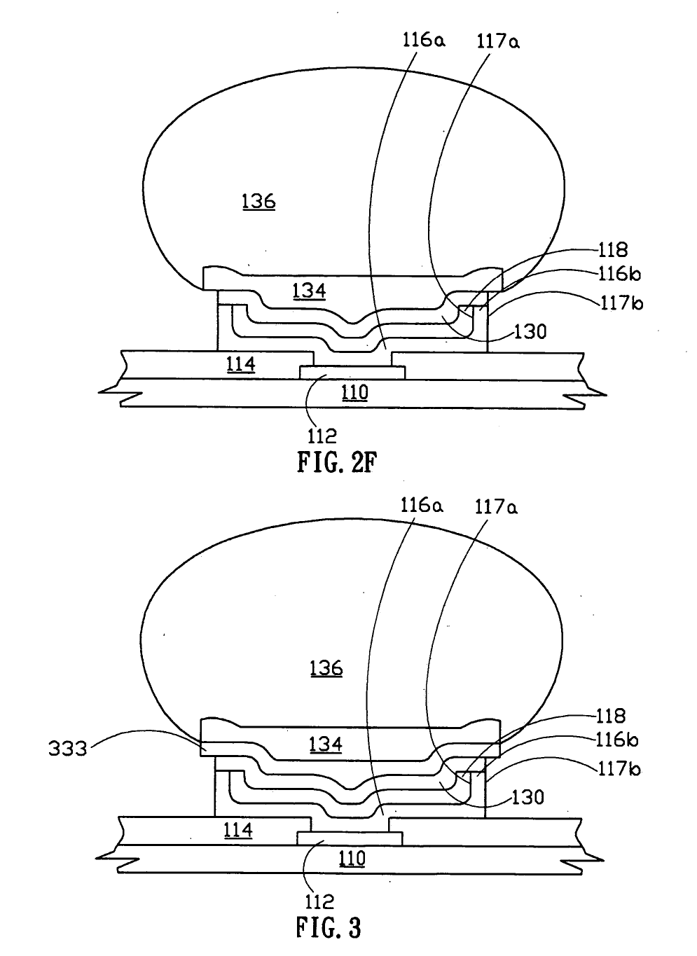

FIG. 2A to FIG. 2F are cross-sectional diagrams illustrating the formation of conductive bumps in accordance with one embodiment of the present invention. Referring to FIG. 2A, a semiconductor structure includes a wafer 110, a conductive structure 112, a dielectric layer 114 and a first photo resist layer 115. In the embodiment, wafer 110 comprises a silicon wafer with or without other semiconductor device thereon. The conductive structure 112, such as an aluminum or copper bond pad formed by any suitable method, is configured to electrically connect with other structure or device. The dielectric layer 114, such as oxide, nitride or other organic component, is a passivation layer for protecting and planarizing the semiconductor structure. A surface 113 is conductive and a part of the conductive structure 112 exposed by the dielectric layer 114. The first photo resist layer 115 is exposed and then developed to form a plurality of openings (one shown in the drawing) by photolithography processes. The first photo resist layer 115 can be a liquid photo resist and is coated and then patterned to form the openings through photolithography processes. Alternatively, the first photo resist layer 115 could be a dry film patterned and overlaid on the dielectric layer 114 through photolithography processes. Furthermore, the openings of the first photo resist layer 115 expose a portion of the dielectric layer 114 and a portion of the surface 113 of the conductive structure 112.

Referring to FIG. 2B, a first conductive barrier layer 116, such as a adhesion/diffusion layer, is conformally formed on the first photo resist layer 115, the portion of the dielectric layer 114 and the surface 113 of the conductive structure 112. In the embodiment, the first conductive barrier layer 116, such as a Ta/TaN-based layer formed by sputtering in the opening of the first photo resist layer 115, has a bottom and a side wall. Next, a conductive wetting layer 118 is conformally formed on the first conductive barrier layer 116 to overlay the bottom and the side wall of the first conductive barrier layer 116. In the embodiment, the conductive wetting layer 118 is implemented by electroplating a copper-based material.

Next referring to FIG. 2C, a removal method which is one of the features of the present invention, such as chemical mechanical polishing, is employed to remove and planarize the first conductive barrier layer 116 and the conductive wetting layer 118 on the first photo resist layer 115. In the step, the bottom and side wall of the first conductive barrier layer 116 in the opening of the first photo resist layer 115 are in a cup shape with a rim consisted of the side walls of the conductive wetting layer 118 and the first conductive barrier layer 116. The side walls of the conductive wetting layer 118 and the first conductive barrier layer 116 reach up to a same top surface. In other words, the first conductive barrier layer 116 in the opening of the first photo resist layer 115 has a bottom 116a and a peripheral flange 116b which has an inside side wall 117a and an outside side wall 117b. It is noted that the top surface is coplanar with the first photo resist layer 115. Thus, the inside side wall 117a protects the inside side wall of the conductive wetting layer 118.

Next, referring to FIG. 2D, the preceded formed dielectric layer 114 is exposed after the removal of the first photo resist layer 115. A conductive seed layer 130, such as a copper-based layer by sputtering, is conformally formed on the dielectric layer 114, the peripheral flange 116b of the first conductive barrier layer 116, the top surface and the conductive wetting layer 118. It is noted that the thickness of the conductive seed layer 130, depends on the sequential deposition of an electrical-plating layer. Next, a second photo resist layer 132, such as a photo resist layer by spin-on coating, is formed on the conductive seed layer 130.

Next, shown in FIG. 2E, a plurality of openings are formed by transferring patterns of the openings into the second photo resist layer 132 through photolithography. The conductive seed layer 130 both on the bottom 116a and the peripheral flange 116b is exposed to the openings in the second photo resist layer 132. Next, a second conductive barrier layer 134 is formed by a filling method such as electroplating into the openings of the second photo resist layer 132 to partially fill the openings. In the embodiment, the material of the second conductive barrier layer 134 comprises a nickel-based material. Next, by printing or electroplating, a conductive material 136 is filled into the openings of the second photo resist layer 132 to cover the second conductive barrier layer 134 for the formation of solder bumps or gold studs in the openings.

Next, shown in FIG. 2F, the second photo resist layer 132 is removed by stripping. The conductive seed layer 130 both on the dielectric layer 114 and the outside side wall 117b of the peripheral flange 116b of the first conductive barrier layer 116 is removed by wet etching. Next, the conductive material 136 is reflowed to form the solder ball or gold stud.

FIG. 3 is a cross-sectional diagram illustrating a conductive bump in accordance with another one embodiment of the present. Different form the structure in FIG. 2F, for consideration on improving the height of the conductive bump, a conductive interlayer 333 comprising a copper-based layer by electroplating is formed in the opening to partially fill and cover the conductive seed layer 130 prior to the filling of the second conductive barrier layer 134.

The under bump metallurgy layer in accordance with the present invention has a first conductive barrier layer with a cup structure, a conductive wetting layer, a conductive seed layer and a second conductive barrier layer. During a reflow process, the first conductive barrier layer would prevent nickel in the conductive material from, diffusing into the conductive wetting layer through the side wall of the under bump metallurgy layer, as well as from reacting with copper in the conductive wetting layer to form IMC (Cu3Sn).

The foregoing description conveys the best understanding of the objectives and advantages of the present invention. Different embodiments may be made of the inventive concept and spirit of this invention. It is to be understood that all matter disclosed herein is to be interpreted merely as illustrative, and not in a limiting sense.

What is claimed is:

1. A conductive bump structure, comprising:
a conductive surface on a wafer;
a first conductive barrier layer on a portion of said conductive surface, wherein said first conductive barrier layer has a bottom and a side wall, and said side wall is connected to said bottom;
a conductive wetting layer covering said bottom and said side wall, wherein said conductive wetting layer and said side wall have a same top surface;
a conductive seed layer covering said conductive wetting layer and said top surface;
a second conductive barrier layer on said conductive seed layer; and
a conductive bump on said second conductive barrier layer.

2. The conductive bump structure of claim 1, further comprising a conductive interlayer between said conductive seed layer and said second conductive barrier layer.

3. The conductive bump structure of claim 2, wherein said conductive interlayer is made of a copper-based material.

4. The conductive bump structure of claim 1, wherein said conductive surface is an aluminum pad.

5. The conductive bump structure of claim 1, wherein said conductive surface is a copperpad.

6. The conductive bump structure of claim 1, wherein said first conductive barrier layer is made of a Ta/TaN-based material.

7. The conductive bump structure of claim 1, wherein said conductive wetting layer is made of a copper-based material.

8. The conductive bump structure of claim 1, wherein said conductive seed layer is made of a copper-based material.

9. The conductive bump structure of claim 1, wherein said second conductive barrier layer is made of a nickel-based material.

10. A conductive bump structure, comprising:
a conductive surface on a wafer;
a under bump metallurgy layer on said conductive surface, wherein said under bump metallurgy layer has
a first conductive barrier layer with a cup shape, said conductive barrier layer with a bottom attaching said conductive surface and a peripheral flange,
a conductive wetting layer covering said bottom and an inside side wall of said peripheral flange, said conductive wetting layer and said peripheral flange reaching up a same top surface,
a conductive seed layer covering said conductive wetting layer and said top surface, and
a second conductive barrier layer on said conductive seed layer; and
a conductive bump on said under bump metallurgy layer.

11. The conductive bump structure of claim 10, further comprising a conductive interlayer between said conductive seed layer and said second conductive barrier layer.

12. The conductive bump structure of claim 11, wherein said conductive interlayer is made of copper-based material.

13. The conductive bump structure of claim 10, wherein said conductive surface is provided by an aluminum pad.

14. The conductive bump structure of claim 10, wherein said conductive surface is provided by a copper pad.

15. The conductive bump structure of claim 10, wherein said first conductive barrier layer is made of a Ta/TaN-based material.

16. The conductive bump structure of claim 10, wherein said conductive wetting layer is made of a copper-based material.

17. The conductive bump structure of claim 10, wherein said conductive seed layer is made of a copper-based material.

18. The conductive bump structure of claim 10, wherein said second conductive barrier layer is made of a nickel-based material.

19. A method of forming an under bump metallurgy, comprising:
forming a conductive surface on a wafer;
forming a photo resist layer on said wafer and a portion of said conductive surface;
conformally forming a first conductive barrier layer on said exposed conductive surface and said photo resist layer, wherein said first conductive barrier layer has a bottom and a side wall,
conformally forming a conductive wetting layer on said first conductive barrier layer; and
removing a portion of said first conductive barrier layer and a portion of said conductive wetting layer to expose a portion of said photo resist layer, wherein said conductive wetting layer and said side wall have a same top surface.

20. The method of claim 19, wherein the step of conformally forming said first conductive barrier layer comprises forming a Ta/TaN-based material by sputtering.

21. The method of claim 19, wherein the step of conformally forming a copper-based material is implemented by sputtering.

22. The method of claim 19, wherein the removing step is implemented by chemical mechanical polishing.

23. A method of forming a bump structure, comprising:
forming a conductive surface on a wafer;
forming a first photo resist layer on said wafer and a portion of said conductive surface;
conformally forming a first conductive barrier layer on said exposed said conductive surface and said first photo resist layer, wherein said first conductive barrier layer has a bottom and a side wall,
conformally forming a conductive wetting layer on said first conductive barrier layer;
removing a portion of said first conductive barrier layer and a portion of said conductive wetting layer to expose a portion of said photo resist layer, wherein said conductive wetting layer and said side wall have a same top surface;
removing said first photo resist layer;
conformally forming a conductive seed layer on said wafer, said top surface and said conductive wetting layer;
forming a second photo resist layer covering a portion of said conductive seed layer and exposing said conductive seed layer positioned on said bottom and said top surface;
electro-plating a second conductive barrier layer on said conductive seed layer;
electro-plating a conductive bump on said second conductive barrier layer; and
removing said second photo resist layer.

24. The method of claim 23, further comprising electro-plating a copper layer between said conductive seed layer and said second conductive barrier layer.

25. The method of claim 23, wherein the step of conformally forming said first conductive barrier layer comprises sputtering a Ta/TaN-based material.

26. The method of claim 23, wherein the step of conformally forming said conductive wetting layer comprises sputtering a copper-based material.

27. The method of claim 23, wherein the removing step is implemented by chemical mechanical polishing.
